(19) United States
(12) Patent Application Publication
(10) Pub. No.: US 2023/0389316 A1
(43) Pub. Date: Nov. 30, 2023

(54) MEMORY DEVICE AND MANUFACTURING METHOD OF THE MEMORY DEVICE

(71) Applicant: SK hynix Inc., Icheon-si Gyeonggi-do (KR)

(72) Inventors: Byung In LEE, Icheon-si Gyeonggi-do (KR); Eun Mee KWON, Icheon-si Gyeonggi-do (KR); In Su PARK, Icheon-si Gyeonggi-do (KR); Hyung Jun YANG, Icheon-si Gyeonggi-do (KR); Sang Heon LEE, Icheon-si Gyeonggi-do (KR); Sung Jae CHUNG, Icheon-si Gyeonggi-do (KR)

(73) Assignee: SK hynix Inc., Icheon-si Gyeonggi-do (KR)

(21) Appl. No.: 17/991,365

(22) Filed: Nov. 21, 2022

(30) Foreign Application Priority Data
May 24, 2022 (KR) 10-2022-0063382

(51) Int. Cl. H01L 29/76

(52) U.S. Cl. CPC H01L 27/11582; H01L 27/11565; H01L 27/11526; H01L 27/11556; H01L 27/11519; H01L 27/11573

(57) ABSTRACT

The present disclosure relates to a memory device and a manufacturing method of the memory device. The memory device according to an embodiment includes a stacked structure including gate lines separated from and stacked on top of each other, a main plug formed in a vertical direction to the stacked structure, a plug separation pattern separating the main plug into first and second sub-plugs, a gap formed in the plug separation pattern; and a separation layer surrounding the gap.

### CROSS-REFERENCE TO RELATED APPLICATION

The present application claims priority under 35 U.S.C. § 119(a) to Korean patent application number 10-2022-0063382 filed on May 24, 2022, in the Korean Intellectual Property Office, the entire disclosure of which is incorporated by reference herein.

### BACKGROUND

### 1. Technical Field

Various embodiments the present disclosure generally relate to a memory device and a method of manufacturing the memory device, and more particularly, to a three-dimensional memory device and a method of manufacturing the three-dimensional memory device.

### 2. Related Art

Memory devices may be classified into volatile memory devices which lose the stored data when power supply is blocked and non-volatile memory devices which retain the stored data even when power supply is blocked.

A non-volatile memory device may include NAND flash memory, NOR flash memory, resistive random access memory (ReRAM), phase-change random access memory (PRAM), magnetoresistive random access memory (MRAM), ferroelectric random access memory (FRAM), and spin transfer torque random access memory (STT-RAM).

A NAND flash memory system may include a memory device configured to store data and a controller configured to control a memory device. The memory device may include a memory cell array storing data and peripheral circuits configured to perform a program, read, or erase operation in response to a command transferred from the controller.

The memory cell array may include a plurality of memory blocks. Each of the memory blocks may include a plurality of memory cells.

As the integration density of the memory device increases, a memory device capable of storing large-capacity data is being required, and simplified manufacturing processes are in demand.

### SUMMARY

According to an embodiment, a stacked structure including gate lines, wherein the gate lines are stacked in a vertical direction, and wherein the gate lines are separated from each other, a main plug included in the stacked structure, the main plug extended in the vertical direction of the stacked structure, a plug separation pattern separating the main plug into first and second sub-plugs,

a gap included in the plug separation pattern and a separation layer surrounding the gap.

According to an embodiment, a method of manufacturing a memory device may include forming a stacked structure in which first and second material layers are alternately stacked on a lower structure, and forming main plugs spaced apart from each other and arranged in a vertical direction to the stacked structure, forming slit holes passing through the stacked structure and separation holes for separating the main plugs, forming a first separation layer on an inner side surface of each of the separation holes, forming a second separation layer on an inner side surface of the first separation layer, forming a third separation layer on an inner side surface of the second separation layer, and forming a gap in the third separation layer.

### BRIEF DESCRIPTION OF THE DRAWINGS

FIG. 1 is a diagram illustrating a memory device according to an embodiment of the present disclosure;

FIG. 2 is a diagram illustrating arrangement of a memory cell array and a peripheral circuit;

FIG. 3 is a diagram illustrating the structure of a memory cell array;

FIG. 4 is a diagram illustrating the layout of a memory device according to an embodiment of the present disclosure;

FIG. 5 is a layout view illustrating the structure of a plug area 41 according to an embodiment of the present disclosure;

FIG. 6 is a cross-sectional view illustrating the structure of a single plug area 42 according to an embodiment of the present disclosure;

FIG. 7 is a cross-sectional view illustrating the structure of a plug separation pattern area 43 according to an embodiment of the present disclosure;

FIG. 8 is a layout view illustrating the structure of a plug area 61 adjoining a source line according to an embodiment of the present disclosure;

FIG. 9 is a perspective view illustrating the structure of a slit and memory blocks according to an embodiment of the present disclosure;

FIGS. 10A, 10B, 10C, 10D, 10E, 10F, 10G, 10H, 10I, 103, 10K, 10L, 10M, 10N, 10O, 10P, and 10Q are layout views illustrating a method of manufacturing a memory device according to an embodiment of the present disclosure;

FIGS. 11A, 11B, 11C, 11D, 11E, 11F, 11G, 11H, 11I, 113, 11K, 11L, 11M, 11N, 11O, 11P, and 11Q are cross-sectional views illustrating a method of manufacturing a memory device according to an embodiment of the present disclosure;

FIG. 12 is a diagram illustrating a solid state drive (SSD) to which a memory device according to the present disclosure is applied; and

FIG. 13 is a diagram illustrating a memory card system to which a memory device according to an embodiment of the present disclosure is applied.

### DETAILED DESCRIPTION

Specific structural or functional descriptions of examples of embodiments in accordance with concepts which are disclosed in this specification are illustrated only to describe the examples of embodiments in accordance with the concepts and the examples of embodiments in accordance with the concepts may be carried out by various forms but the descriptions are not limited to the examples of embodiments described in this specification.

Various embodiments are directed to a memory device capable of improving the reliability the memory device and a method of operating the memory device.

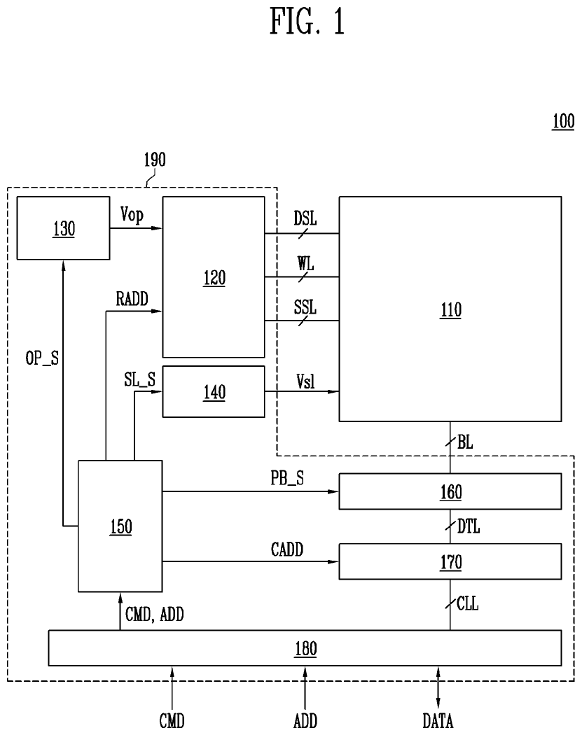

FIG. 1 is a diagram illustrating a memory device 100 according to an embodiment of the present disclosure.

Referring to FIG. 1, the memory device 100 may include a peripheral circuit 190 and a memory cell array 110.

The peripheral circuit 190 may perform a program operation and a verify operation for storing data in the memory cell array 110, a read operation for outputting the data stored in the memory cell array 110, or an erase operation for erasing the data stored in the memory cell array 110. The peripheral circuit 190 may include a voltage generator 130, a row decoder 120, a source line driver 140, a control circuit 150, a page buffer 160, a column decoder 170, and an input/output circuit 180.

The memory cell array 110 may include a plurality of memory cells that store data. According to an embodiment, the memory cell array 110 may include a three-dimensional memory cell array. The plurality of memory cells may store single bit data or multi-bit data consisting of two or more bits according to a program method. The plurality of memory cells may form a plurality of strings. Memory cells which are included in each of the strings may be electrically coupled to each other through a channel. Channels included in the strings may be coupled to the page buffer 160 through bit lines BL.

The voltage generator 130 may generate various operating voltages Vop for a program operation, a read operation, or an erase operation in response to an operation signal OP_S. For example, the voltage generator 130 may selectively generate and output various operating voltages Vop that include a program voltage, a verify voltage, a pass voltage, a read voltage, and an erase voltage.

The row decoder 120 may be coupled to the memory cell array 110 through a plurality of drain select lines DSL, a plurality of word lines WL, and a plurality of source select lines SSL. The row decoder 120 may transfer the operating voltages Vop to the plurality of drain select lines DSL, the plurality of word lines WL, and the plurality of source select lines SSL in response to a row address RADD.

The source line driver 140 may transfer a source voltage Vsl to the memory cell array 110 in response to a source line signal SL_S. For example, the source voltage Vsl may be transferred to a source line which is coupled to the memory cell array.

The control circuit 150 may output the operation signal OP_S, the row address RADD, a source line control signal SL_S, a page buffer control signal PB_S, and a column address CADD in response to a command CMD and an address ADD.

The page buffer 160 may be coupled to the memory cell array 110 through the bit lines BL. The page buffer 160 may store data DATA received through the plurality of bit lines BL in response to the page buffer control signal PB_S. The page buffer 160 may sense voltages or currents in the plurality of bit lines BL during a read operation.

The column decoder 170 may transfer the data DATA, which is input from the input/output circuit 180, to the page buffer 160, or may transfer the data DATA stored in the page buffer 160 to the input/output circuit 180 in response to the column address CADD. The column decoder 170 may exchange the data DATA with the input/output circuit 180 through column lines CLL and may exchange the data DATA with the page buffer 160 through data lines DTL.

The input/output circuit 180 may transfer the command CMD and the address ADD, which are transferred from the external device (e.g., a controller) coupled to the memory device 100, to the control circuit 150, and may output the data DATA received from the column decoder 170 to the external device.

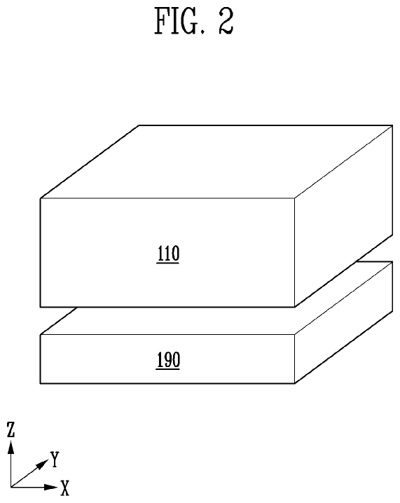

FIG. 2 is a diagram illustrating the arrangement of the memory cell array 110 and the peripheral circuit 190.

Referring to FIG. 2, the memory cell array 110 may be stacked over the peripheral circuit 190. For example, when a substrate is formed in an X-Y plane, the peripheral circuit 190 may be stacked in a Z direction from the substrate, and the memory cell array 110 may be stacked over the peripheral circuit 190.

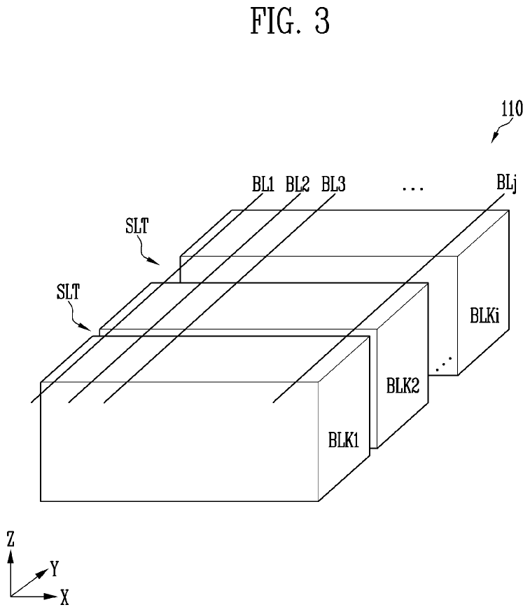

FIG. 3 is a diagram illustrating the structure of the memory cell array 110.

Referring to FIG. 3, the memory cell array 110 may include first to ith memory blocks BLK1 to BLKi, where i is a positive integer. The first to ith memory blocks BLK1 to BLKi may be spaced apart from each other in a Y direction and coupled in common to first to jth bit lines BL1 to BLj. For example, the first to jth bit lines BL1 to BLj may extend in the Y direction and be spaced apart from each other in the X direction. The first to ith memory blocks BLK1 to BLKi may be separated from each other by slits SLT.

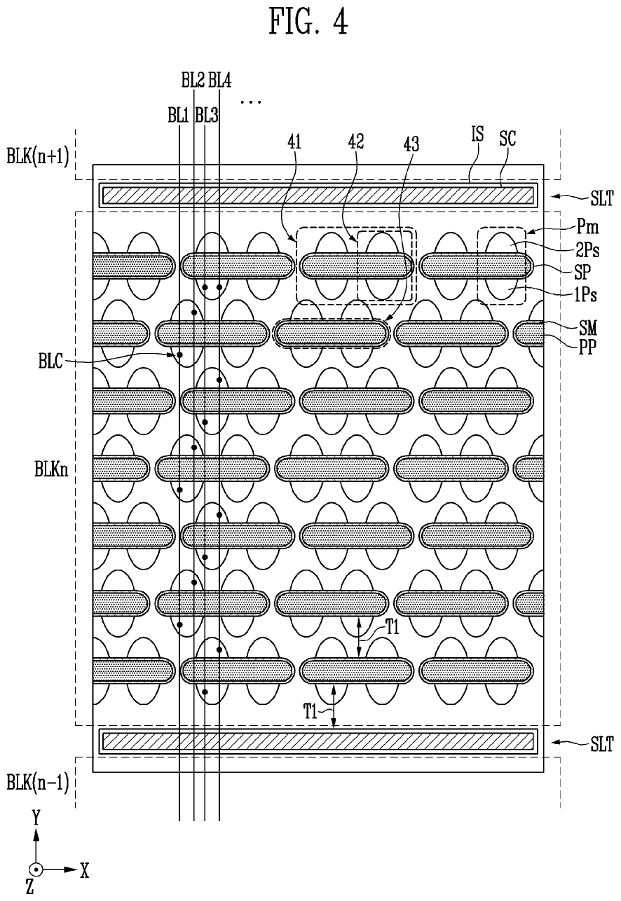

FIG. 4 is a diagram illustrating the layout of a memory device according to an embodiment of the present disclosure.

Referring to FIG. 4, an (n−1)th memory block BLK(n−1), an nth memory block BLKn, and an (n+1)th memory block BLK(n+1) which are included in the memory device may be spaced apart from each other in the Y direction. The (n−1)th memory block BLK(n−1), the nth memory block BLKn, and the (n+1)th memory block BLK(n+1) may have the same configuration, and may be separated from each other by the slits SLT. Each of the slits SLT may include a slit isolation layer IS and a source contact SC. The slit isolation layer IS may electrically block the memory blocks from each other. The source contact SC may contact a source line (not shown) which is formed under the memory blocks and may transfer a source line voltage generated by the voltage generating circuit to the source line.

Since (n−1)th memory block BLK(n−1), the nth memory block BLKn, and the (n+1)th memory block BLK(n+1) may have the same configuration, the nth memory block BLKn will be described below as an example.

The nth memory block BLKn may include a plurality of main plugs Pm. The main plug Pm may include first and second sub-plugs 1Ps and 2Ps which are separated by a plug separation pattern SP. Each of the first and second sub-plugs 1Ps and 2Ps may include a plurality of memory cells. FIG. 4 illustrates that each of the two main plugs Pm is separated into the first and second sub-plugs 1Ps and 2Ps by one plug separation pattern SP. However, the number of main plugs Pm separated by one plug separation pattern SP is not limited to the number shown in FIG. 14. For example, one main plug Pm may be separated into the first and second sub-plugs 1Ps and 2Ps by one plug separation pattern SP. Each of the three main plugs Pm may be separated into the first and second sub-plugs 1Ps and 2Ps by one plug separation pattern SP. Hereinafter, an embodiment in which each of the two main plugs Pm is separated into the first and second sub-plugs 1Ps and 2Ps by one plug separation pattern SP will be described.

Since different bit lines BL are coupled to the first and second sub-plugs 1Ps and 2Ps, memory cells included in the first and second sub-plugs 1Ps and 2Ps may form different strings. For example, the first sub-plug 1Ps may be coupled to the first bit line BL1 through a bit line contact BLC, and the second sub-plug 2Ps may be coupled to the second bit line BL2 through the bit line contact BLC.

The nth memory block BLKn may include source select lines, word lines, and drain select lines which are stacked on top of each other. For example, the word lines may be formed over the source select lines, and the drain select lines may be formed over the word lines.

Since the (n−1)th to (n+1)th memory blocks BLK(n−1) to BLK(n+1) are separated by the slits SLT, gate lines included in different memory blocks may be separated from each other by the slits SLT. For example, the gate lines included in the (n−1)th memory block BLK(n−1) and the gate lines included in the nth memory block BLKn may be separated from each other by the slit SLT.

According to an embodiment of the present disclosure, the plug separation patterns SP may be separated at a predetermined interval from the slit SLT in the Y-axis direction. In addition, the plug separation patterns SP may be spaced apart from each other by the interval from the slit SLT in a Y-axis direction. For example, the plug separation patterns SP may be separated from the slit SLT at a first interval T1 in the Y-axis direction. The word “predetermined” as used herein with respect to a parameter, such as a predetermined interval, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm.

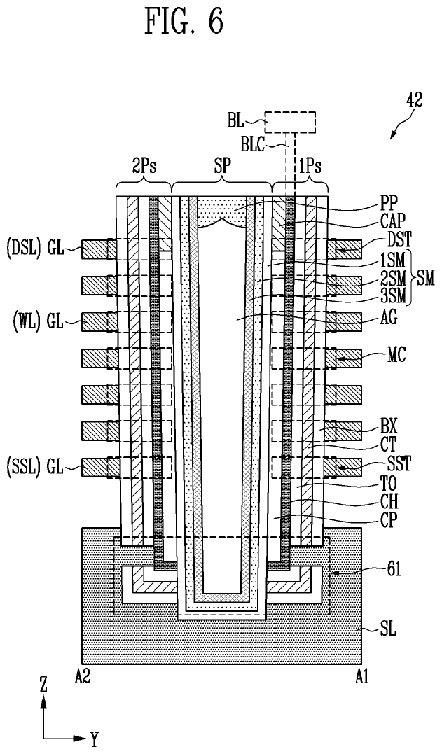

Each of the plug separation patterns SP may include a blocking pattern PP, an air gap (not shown), and a separation layer SM. The blocking pattern may surrounded by the separation layer over the gap. The separation layer SM and the blocking pattern PP may block the air gap from exchanging materials with the outside. Thus, the air gap may be formed under the blocking pattern PP in a Z-axis direction. The air gap over the separation layer SM will be described below with reference to FIG. 6. The separation layer SM may have various shapes and is not limited to the shape shown in FIG. 4. For example, the separation layer SM may have an elliptical shape, a circular shape, a rectangular shape, or the like.

A plug area 41 which includes memory cells will be described below.

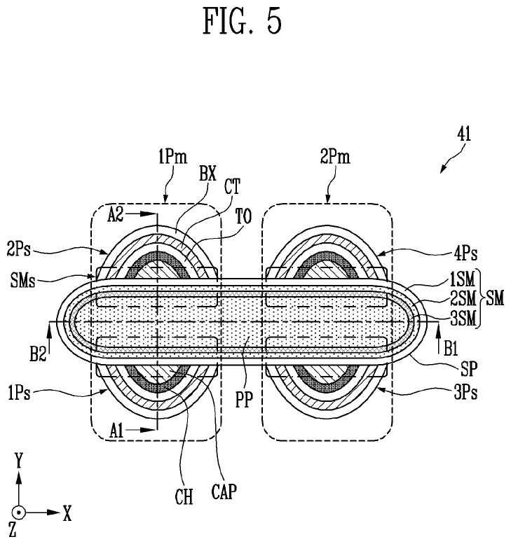

FIG. 5 is a layout view illustrating the structure of the plug area 41 according to an embodiment of the present disclosure.

Referring to FIG. 5, the first and second main plugs 1Pm and 2Pm and the plug separation pattern SP may be included in the plug area 41. The first and second main plugs 1Pm and 2Pm may be spaced apart from each other in an X-axis direction and extend in the Y-axis direction. The plug separation pattern SP may extend in the X-axis direction to separate the first and second main plugs 1Pm and 2Pm in the Y-axis direction.

The first main plug 1Pm may include the first and second sub-plugs 1Ps and 2Ps which are separated by the plug separation pattern SP. The second main plug 2Pm may include third and fourth sub-plugs 3Ps and 4Ps which are separated by the plug separation pattern SP. The third sub-plug 3Ps may have the same structure as the first sub-plug 1Ps. The fourth sub-plug 4Ps may have the same structure as the second sub-plug 2Ps. The structure of the first sub-plug 1Ps may be symmetrical to that of the second sub-plug 2Ps on the basis of the plug separation pattern SP. The structure of the third sub-plug 3Ps may be symmetrical to that of the fourth sub-plug 4Ps on the basis of the plug separation pattern SP.

Since the first to fourth sub-plugs 1Ps to 4Ps have similar structures, the structure of the first sub-plug 1Ps will be described below as an example.

The first sub-plug 1Ps may include a capping layer CAP, a channel layer CH, a tunnel isolation layer TO, a charge trap layer CT, and a blocking layer BX. The capping layer CAP may be arranged at a top portion of the first sub-plug 1Ps which is extended a vertical direction from the substrate, and may, in an embodiment, be provided to improve electrical characteristics of drain select transistors. For example, the capping layer CAP may include a conductive material. For example, the capping layer CAP may include a doped polysilicon layer. Though not shown in FIG. 5, a core pillar CP may be formed under the capping layer CAP. For example, the core pillar CP may include an insulating material or a conductive material. The channel layer CH may surround the capping layer CAP and the core pillar CP, and may include a conductive material. For example, the channel layer CH may include a polysilicon layer. The tunnel isolation layer TO may surround the channel layer CH and include an insulating material. For example, the tunnel isolation layer TO may include an oxide layer or a silicon oxide layer. The charge trap layer CT may surround the surface of the tunnel isolation layer TO and may include a material capable of trapping charges. For example, the charge trap layer CT may include a nitride layer. The blocking layer BX may surround the charge trap layer CT and include an insulating material. For example, the blocking layer BX may include an oxide layer or a silicon oxide layer.

Though not shown in FIG. 5, the first to fourth sub-plugs 1Ps to 4Ps may be electrically coupled to different bit lines through different bit line contacts. For example, the channel layer CH of the first sub-plug 1Ps may be coupled to the first bit line through the bit line contact, the channel layer CH of the second sub-plug 2Ps may be coupled to the second bit line through the bit line contact, the channel layer CH of the third sub-plug 3Ps may be coupled to the third bit line through the bit line contact, and the channel layer CH of the fourth sub-plug may be coupled to the fourth bit line through the bit line contact BLC.

Though not shown in FIG. 5, the air gap may be extended in the Z-axis direction of the blocking pattern PP. The plug separation pattern SP may include the blocking pattern PP, the air gap, and the separation layer SM surrounding the air gap and the blocking pattern PP. The separation layer SM may include a sub-separation region SMs corresponding to a portion of the separation layer SM which contacts the first to fourth sub-plugs 1Ps to 4Ps. Similarly, to the first to fourth sub-plugs 1Ps to 4Ps having similar configurations, the sub-separation regions SMs which contact the first to fourth sub-plugs 1Ps to 4Ps, respectively, may have similar configurations. In addition, similarly to the first to fourth sub-plugs 1Ps to 4Ps which are symmetrical with respect to the plug separation pattern SP, each of the sub-separation regions SMs which contact the first to fourth sub-plugs 1Ps to 4Ps, respectively, may be symmetrical to the plug separation pattern SP.

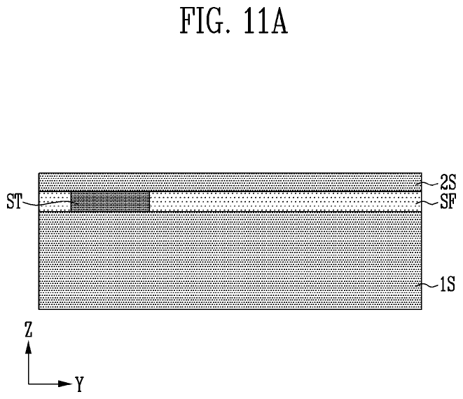

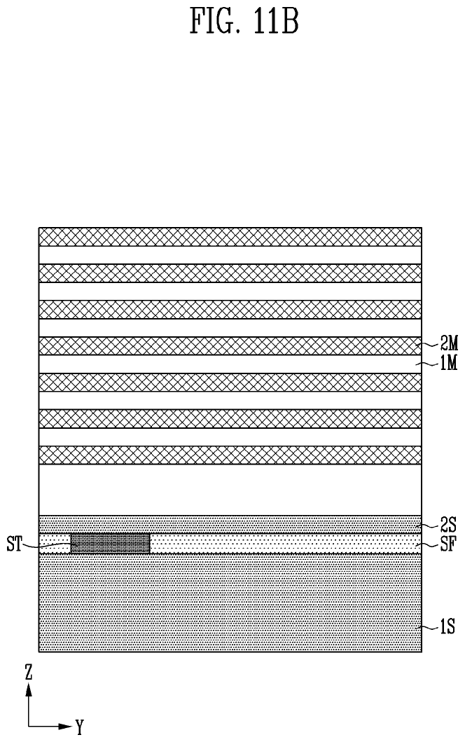

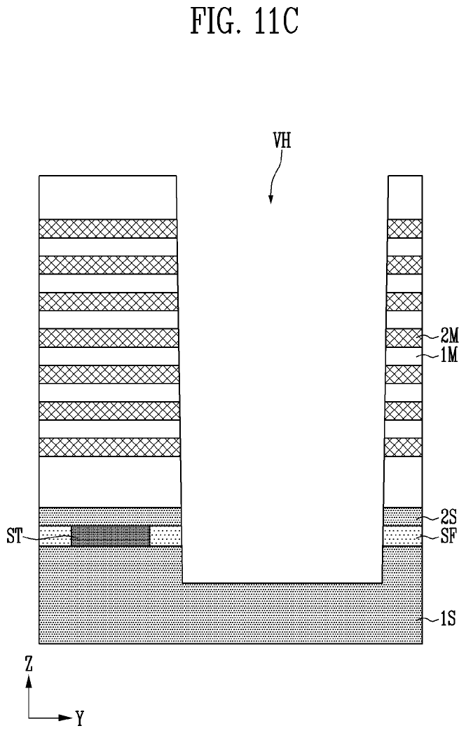

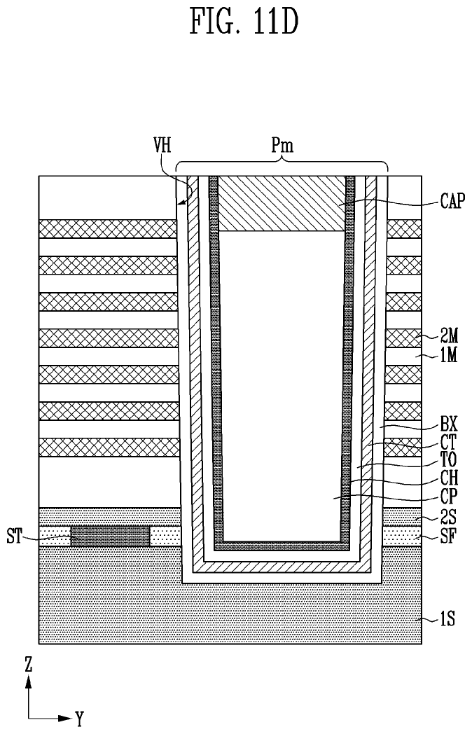

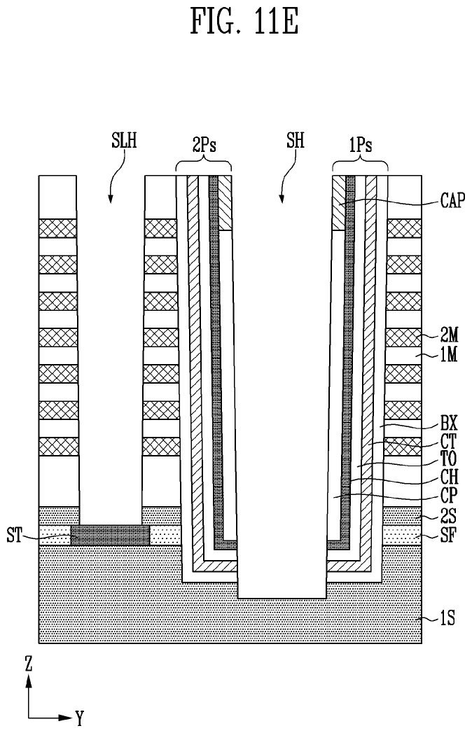

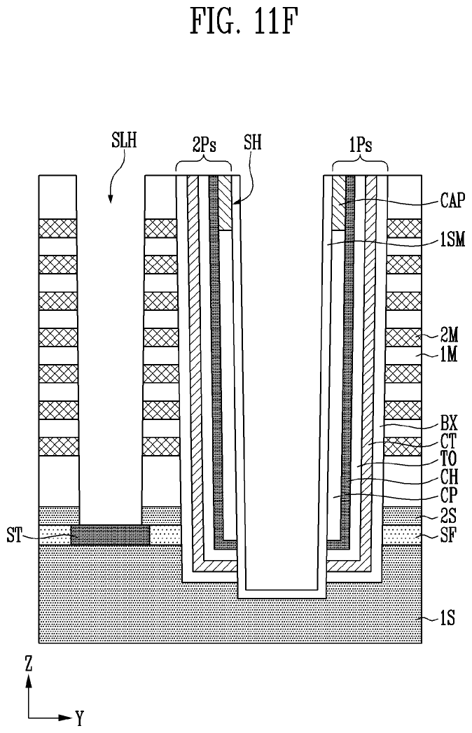

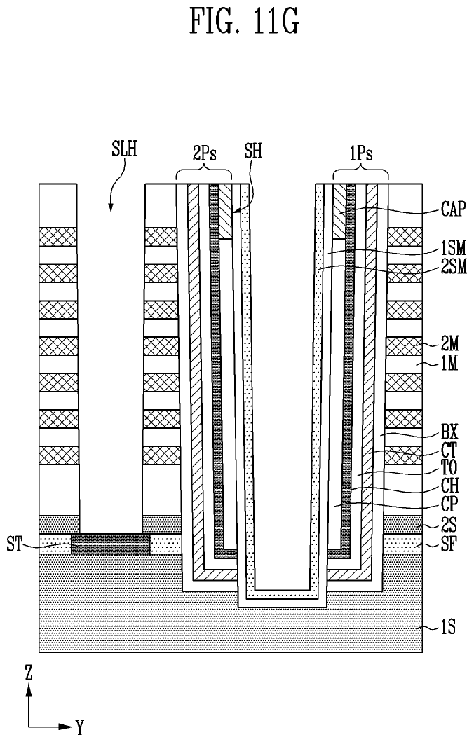

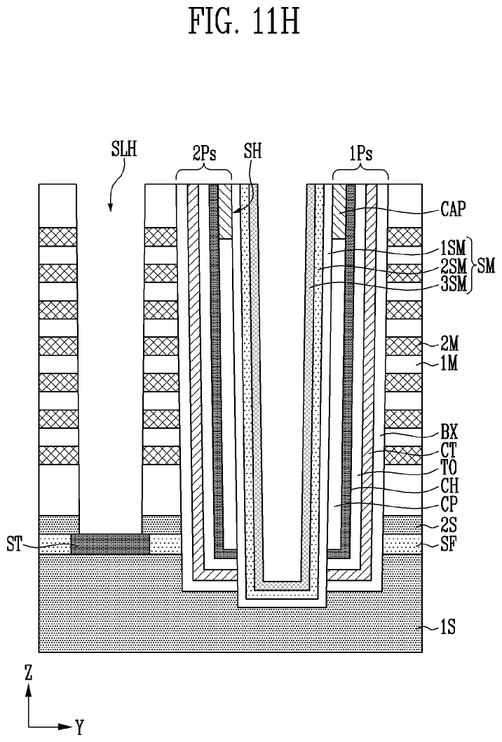

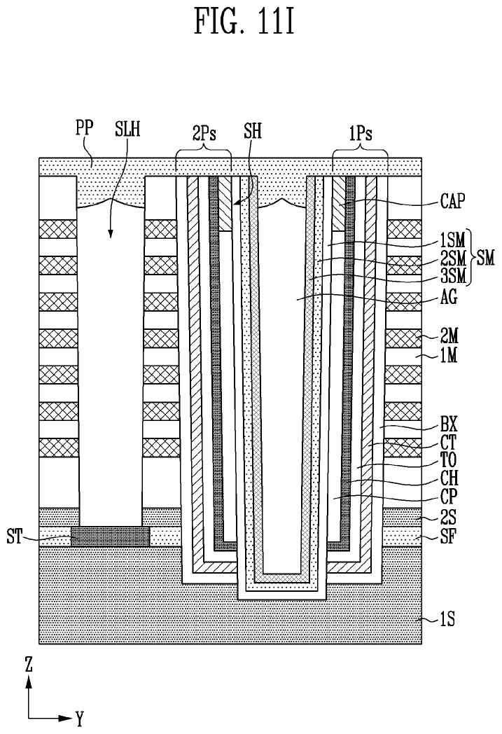

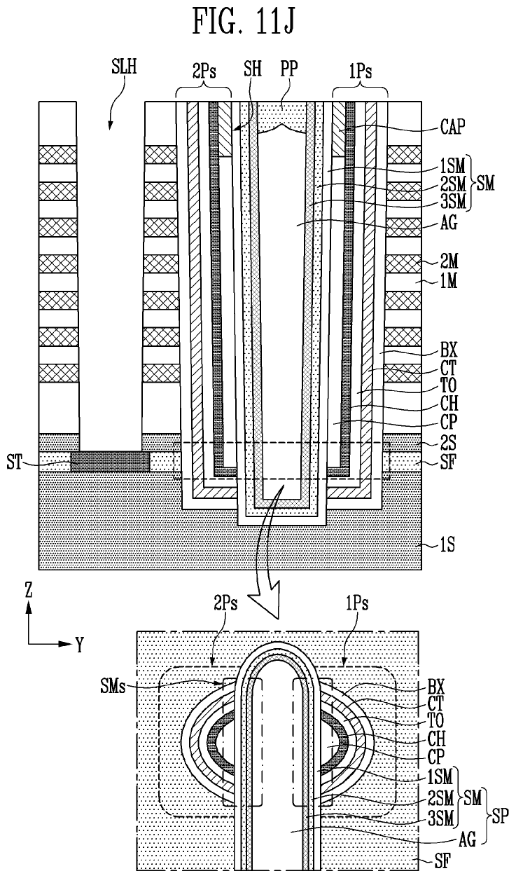

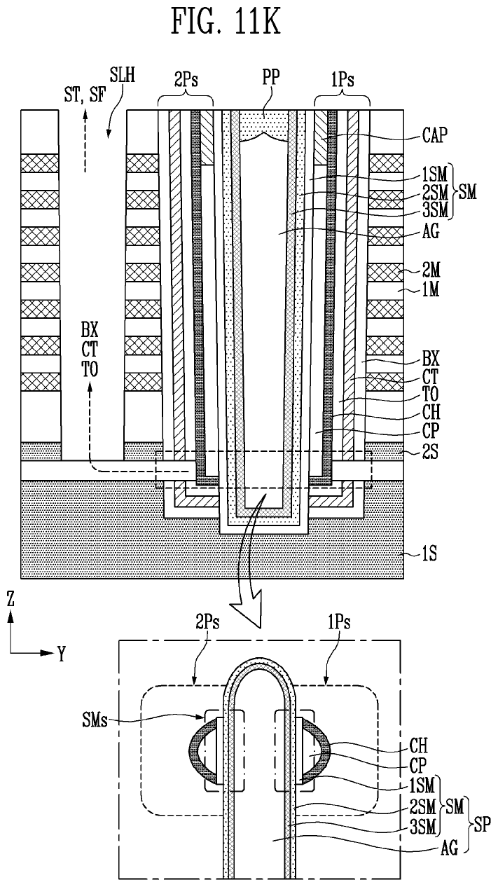

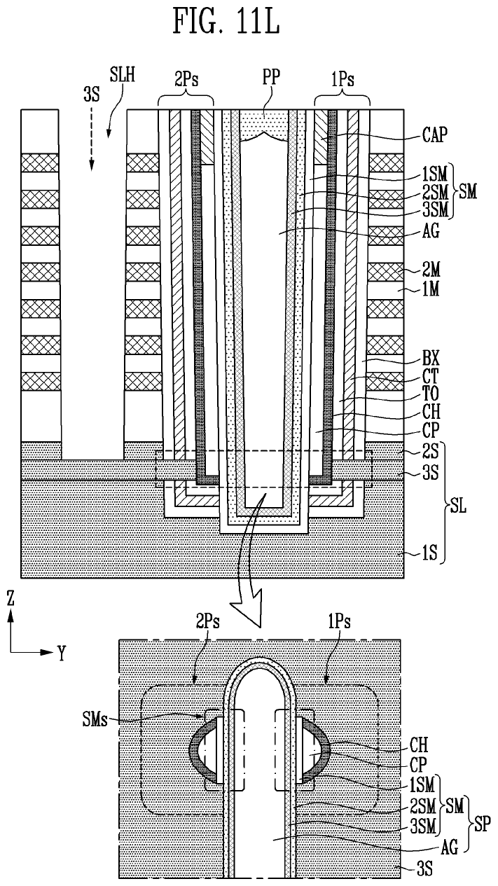

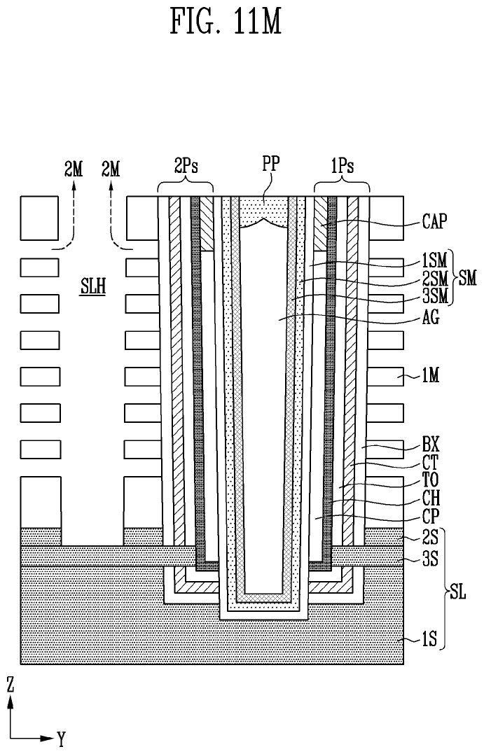

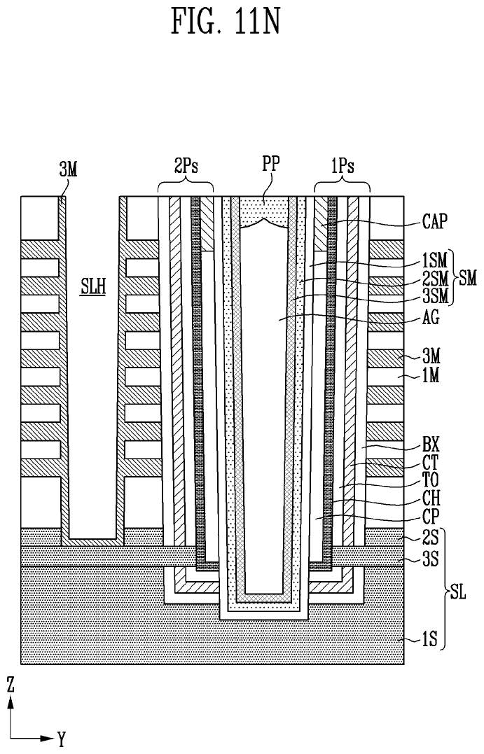

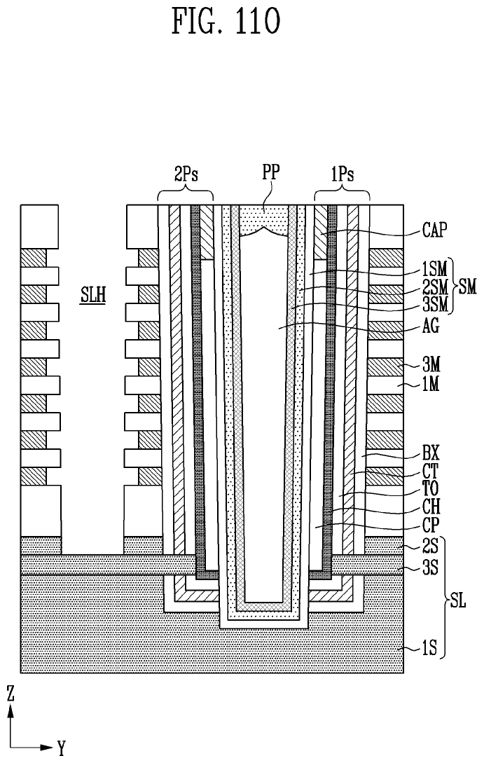

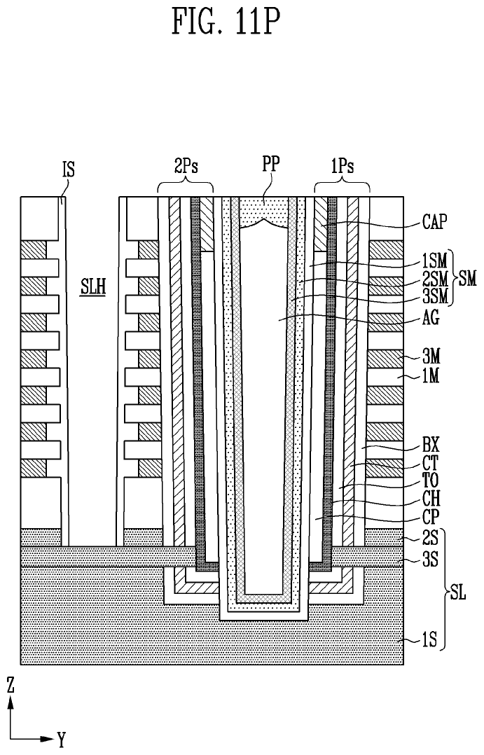

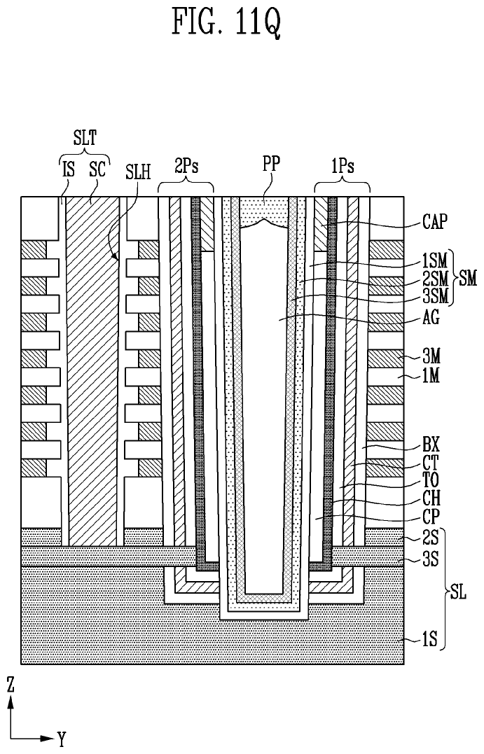

The separation layer SM may include first to third separation layers 1SM to 3SM. The first separation layer 1SM may surround an outermost edge of the separation layer SM. The second separation layer 2SM may be formed on an inner wall of the first separation layer 1SM. The third separation layer 3SM may be formed along an inner wall of the second separation layer 2SM. The first separation layer 1SM may include an insulating material, for example, an oxide layer or a silicon oxide layer. The first separation layer 1SM may, in an embodiment, protect layers which are exposed through a side surface of a separation hole SH in FIG. 11E, and may electrically block the second separation layer 2SM and the first to fourth sub-plugs 1Ps to 4Ps from each other before the separation layer SM is formed. In addition, the first separation layer 1SM may, in an embodiment, block a source line conductive material from being introduced into memory cells during a source line forming process to be performed in subsequent processes.

The second separation layer 2SM may include a low-k material. The low-k material means a material that has a small relative dielectric constant (k) relative to silicon dioxide (SiO2). For example, the second separation layer 2SM might include a SiCN layer. To control capacitance of a memory cell, the carbon (C) content may be adjusted when the second separation layer 2SM is formed. The second separation layer 2SM may, in an embodiment, be provided to reduce interference between memory cells facing each other with the separation layer SM interposed therebetween. For example, capacitance of the second separation layer 2SM may be proportional to the concentration of carbon (C) included in the second separation layer 2SM. In addition, the second separation layer 2SM may, in an embodiment, block a source line conductive material together with the first separation layer 1SM from being introduced into the memory cells during the source line forming process to be performed in subsequent processes. The third separation layer 3SM may surround the blocking pattern PP. The third separation layer 3SM may include an insulating material, for example, a silicon nitride layer or an oxide layer.

In addition, the third separation layer 3SM may block a source line conductive material together with the first and second separation layers 1SM and 2SM from being introduced into the memory cells during the source line forming process to be performed in subsequent processes. As shown in FIG. 5, the separation layer SM may include the third separation layer 3SM, the second separation layer 2SM, and the first separation layer 1SM. However, the separation layer SM may have another configuration. For example, the sub-separation region SMs may include the first separation layer 1SM and the second separation layer 2SM. In addition, as shown in FIG. 5, the third separation layer 3SM, the second separation layer 2SM, and the first separation layer 1SM may have the same thickness. However, the present disclosure might not be limited thereto. For example, when the separation layer SM includes the first separation layer 1SM and the second separation layer 2SM, the second separation layer 2SM may have a greater thickness than the first separation layer 1SM.

The structures of the first and second sub-plugs 1Ps and 2Ps and the plug separation pattern SP will be described with reference to FIG. 6.

FIG. 6 is a layout view illustrating the structure of the single plug area 42 according to an embodiment of the present disclosure.

FIG. 6 shows a cross-section of the first and second sub-plugs 1Ps and 2Ps of FIG. 5 taken along in a direction A1-A2.

The first and second sub-plugs 1Ps and 2Ps and the plug separation pattern SP may be extended in a vertical direction to the source line SL. The plug separation pattern SP may include an air gap AG, the blocking pattern PP, and the separation layer SM. A lower surface of the air gap AG and the separation layer SM of the plug separation pattern SP may contact the source line SL. The blocking pattern PP may be formed on a top portion of the air gap AG. In addition, a lower surface of the blocking pattern PP may have the same width as the top portion of the air gap AG. The blocking pattern PP may block the air gap AG from exchanging materials with the outside by the blocking pattern PP. In an embodiment, the air gap AG may be a gap filled with a gas not limited to air. For example, the gap may include a gas or a combination of gas and air.

The plug separation pattern SP may pass through the core pillar CP, the channel layer CH, the tunnel isolation layer TO, the charge trap layer CT, and the blocking layer BX. The main plug Pm may be separated into the first and second sub-plugs 1Ps and 2Ps by the plug separation pattern SP. The gate lines GL may surround the first and second sub-plugs 1Ps and 2Ps and the plug separation pattern SP and be spaced apart from each other in the Z-axis direction. A lower portion of the channel layer CH may contact the source line SL and an upper portion of the channel layer CH may contact the bit line contact BLC.

Lines which are formed under the word line WL, among the gate lines GL, may serve as source select lines SSL. Lines which are above the word line WL may serve as drain select lines DSL. The word line WL may be coupled to a gate of the memory cell MC. The source select line SSL may be coupled to a gate of the source select transistor SST. The drain select line DSL may be coupled to a gate of the drain select transistor DST. The source select transistor SST may be configured to electrically couple or block the source line SL to or from the channel layer CH in the string. The drain select transistor DST may be configured to electrically couple or block the bit line to or from the channel layer CH in the string.

The bit line contact BLC may be formed on the channel layer CH of the first sub-plug 1Ps. The bit line BL may be formed over the bit line contact BLC.

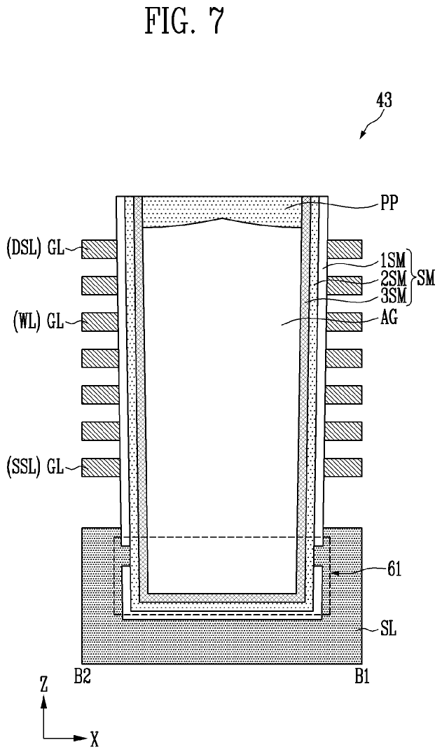

FIG. 7 is a cross-sectional view illustrating the structure of a plug separation pattern area 43 according to an embodiment of the present disclosure.

FIG. 7 shows a cross-section of the plug separation pattern SP shown in FIG. 5 taken in a direction B1-B2. The plug separation pattern SP may include the blocking pattern PP, the air gap AG, and the separation layer SM. The blocking pattern PP may be formed on the top portion of the air gap AG. A bottom surface of the separation layer SM may contact the source line SL. In the plug separation pattern area 43 except for a plug area 61 which contacts the source line SL, the separation layer SM may include the first separation layer 1SM, the second separation layer 2SM, and the third separation layer 3SM. However, the sub-separation area (not shown) corresponding to a portion of the separation layer SM which contacts the plug in the plug area 61 may include the first separation layer 1SM, the second separation layer 2SM, and the third separation layer 3SM. The other portion of the separation layer SM may include the second separation layer 2SM and the third separation layer 3SM.

The structure of the plug area 61 in contact with the source line SL will be described below.

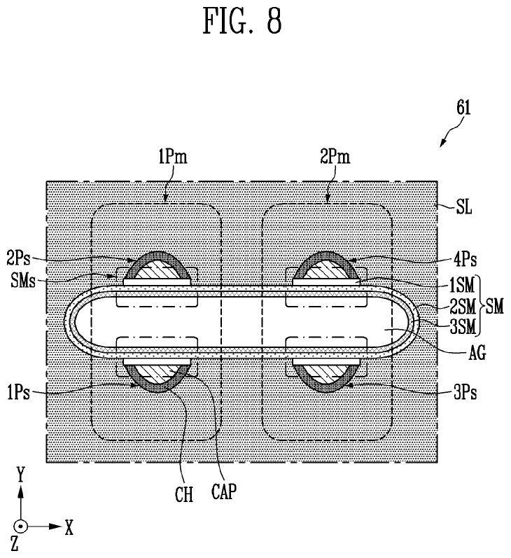

FIG. 8 is a layout view illustrating the structure of the plug area 61 in contact with the source line SL according to an embodiment of the present disclosure.

Referring to FIGS. 5 and 8, the first and second main plugs 1Pm and 2Pm and the plug separation pattern SP may be located in the plug area 61 which contacts the source line SL. The plug separation pattern SP may include the air gap AG and the separation layer SM. The separation layer SM may include the sub-separation region SMs which contacts the first to fourth sub-plugs 1Ps to 4Ps. The sub-separation region SMs may include the third separation layer 3SM, the second separation layer 2SM, and the first separation layer 1SM. The second separation layer 2SM and the third separation layer 3SM may be included in regions of the separation layer SM, except for the sub-separation region SMs. However, this is limited to the plug area 61 which contacts the source line SL. For example, in the plug area in contact with the source line SL, the separation layer SM, except for the sub-separation region SMs, may include both the second separation layer 2SM and the third separation layer 3SM except for the first separation layer 1SM. In the other areas, the separation layer SM may include all the first, second and third separation layers 1SM, 2SM, and 3SM. In the other words, in the sub-separation region SMs, the first separation layer 1SM overlaps with the first and second sub-plugs 1Ps and 2Ps.

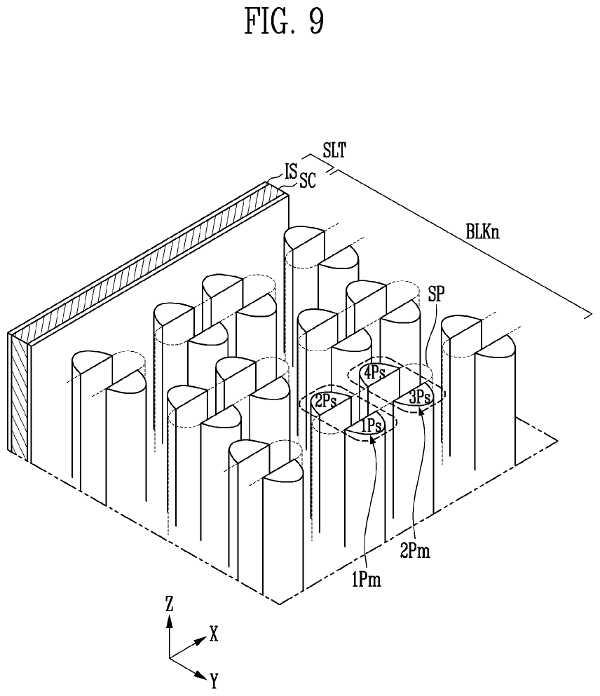

FIG. 9 is a perspective view illustrating the structure of a slit and memory blocks according to an embodiment of the present disclosure.

Referring to FIG. 9, nth memory blocks BLKn having a three-dimensional structure may include the plurality of sub plugs 1Ps to 4Ps which are extended in a vertical direction to a substrate (not shown). For example, the first and second sub-plugs 1Ps and 2Ps may be separated from each other by the separation pattern SP, and the third and fourth sub-plugs 3Ps and 4Ps may also be separated from each other by the separation pattern SP.

The slit SLT which is formed between the memory blocks may be extended in the vertical direction to the substrate (not shown) and extend in the X direction. The slit SLT may include the source contact SC and the slit isolation layer IS.

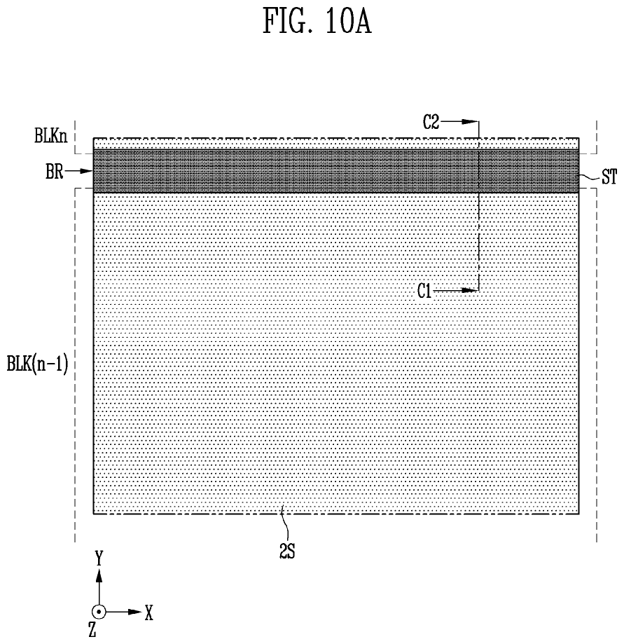

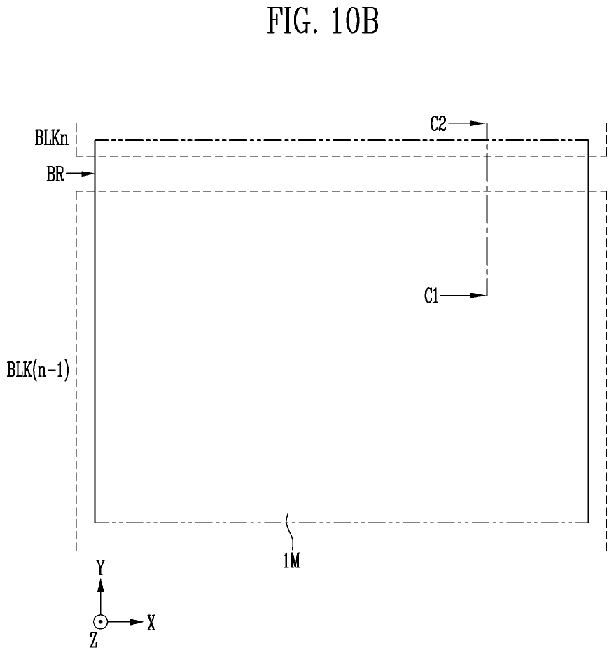

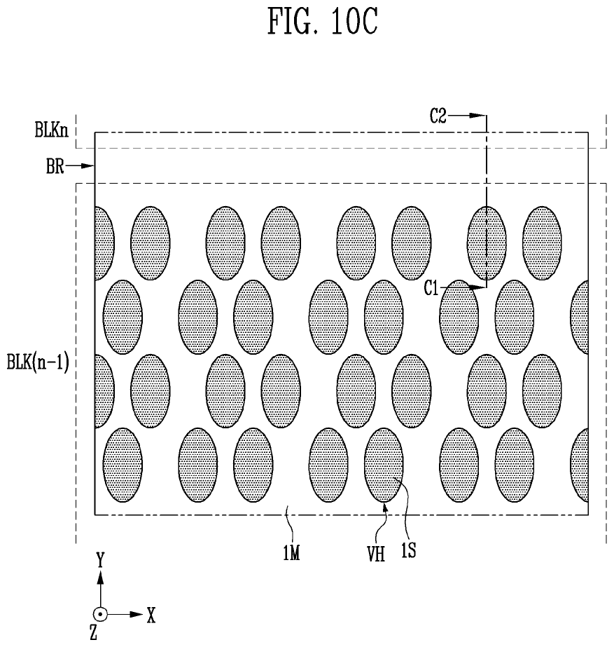

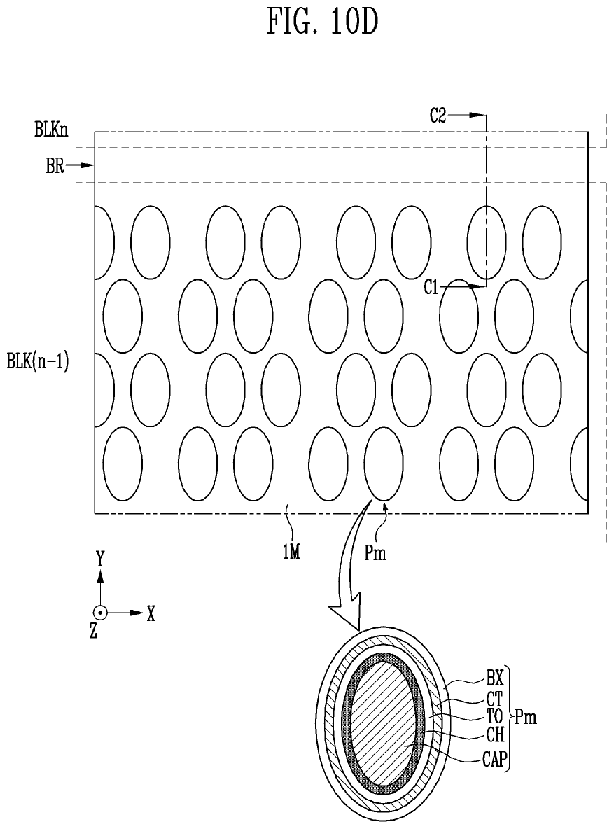

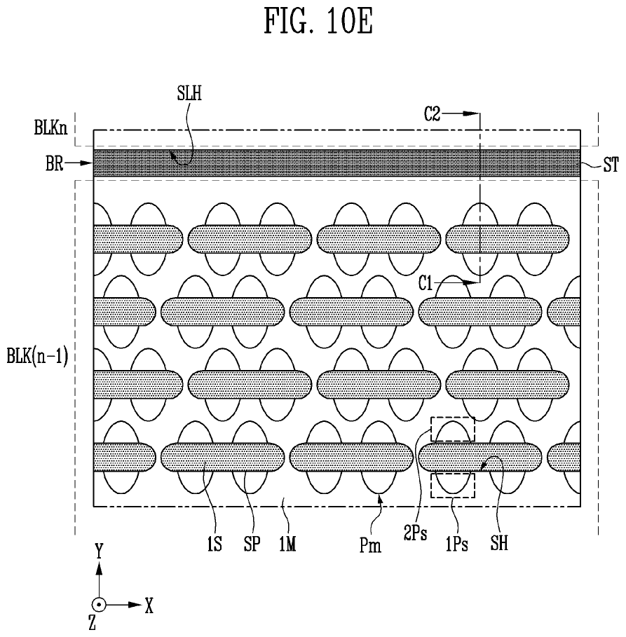

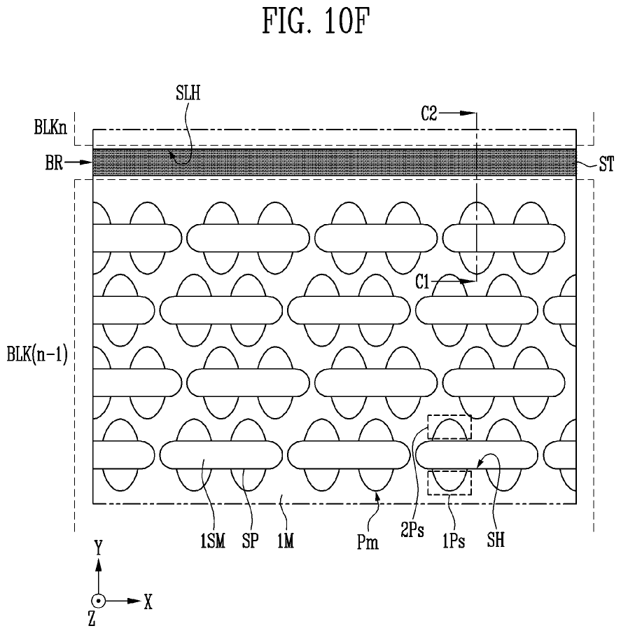

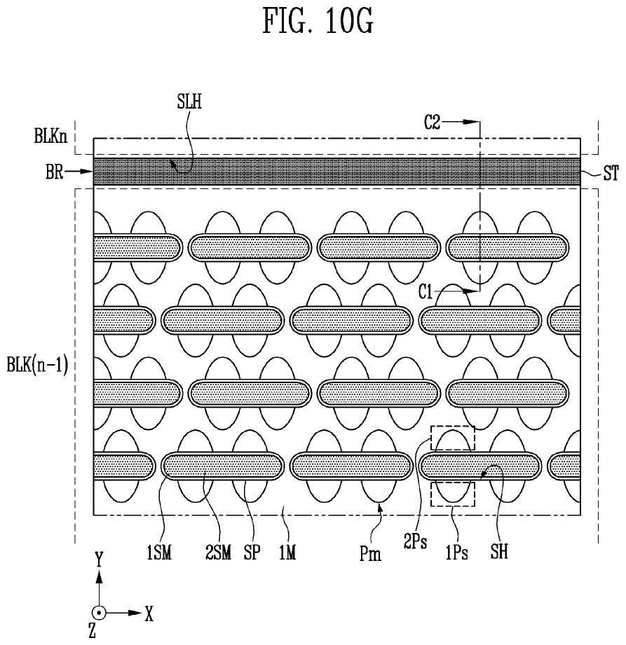

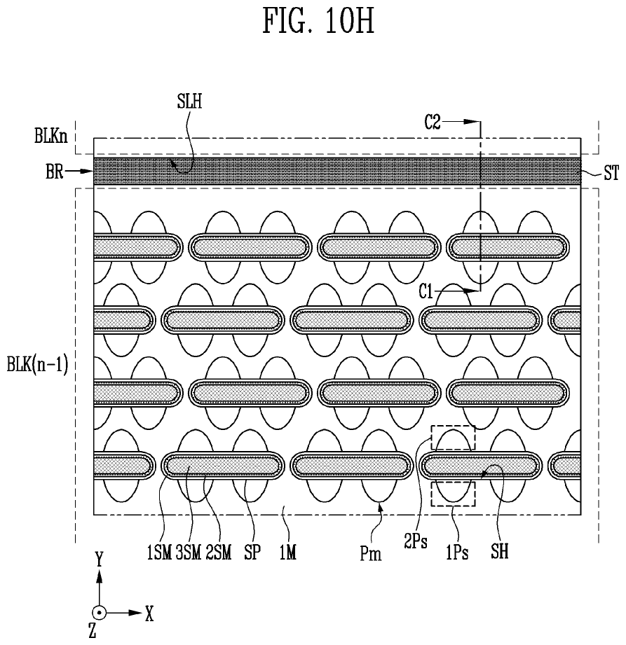

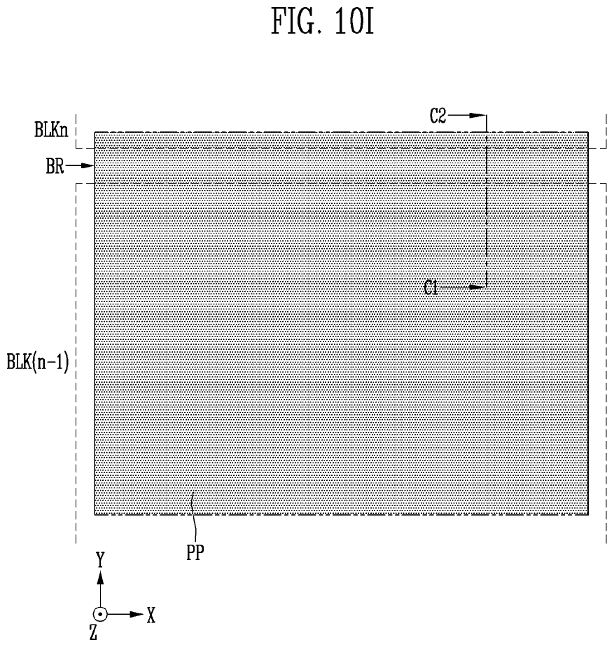

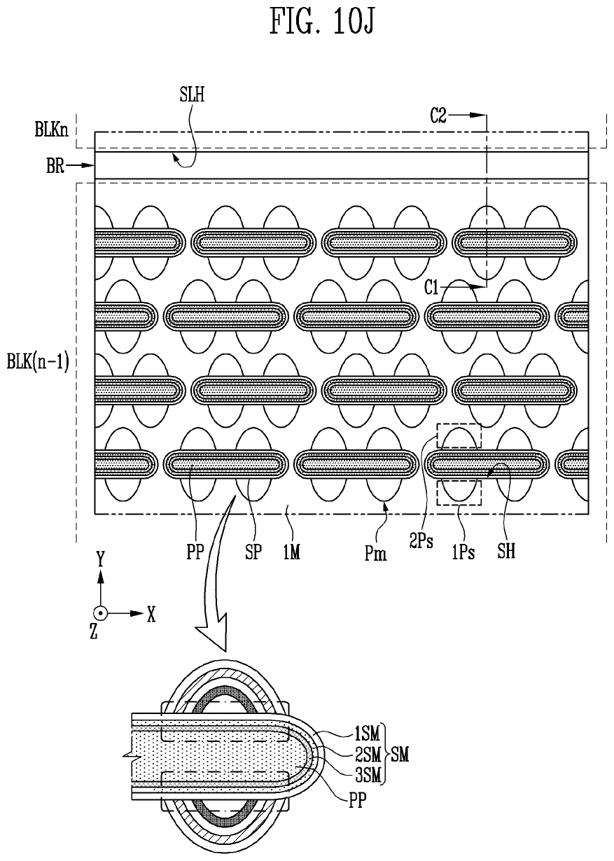

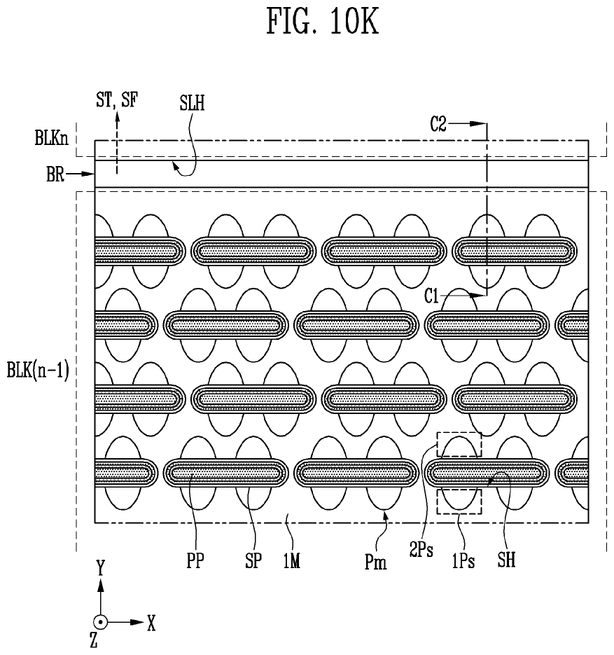

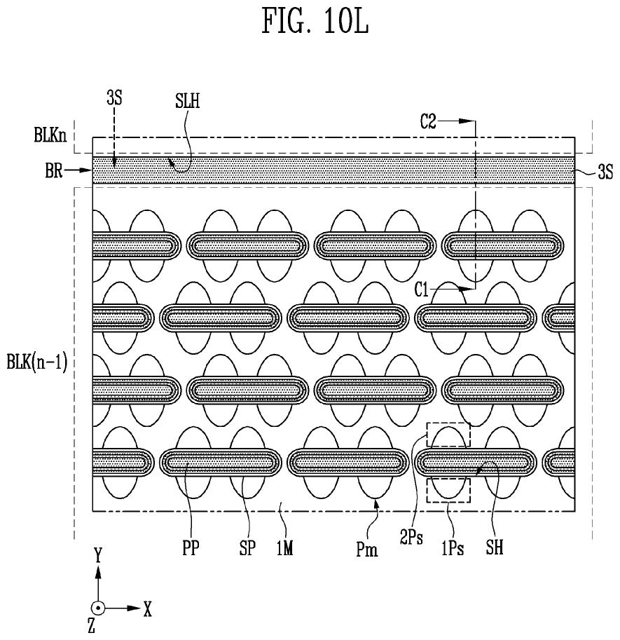

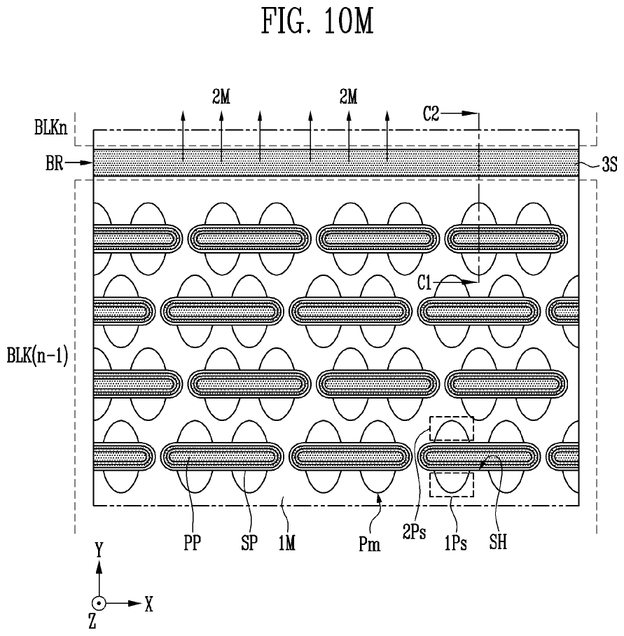

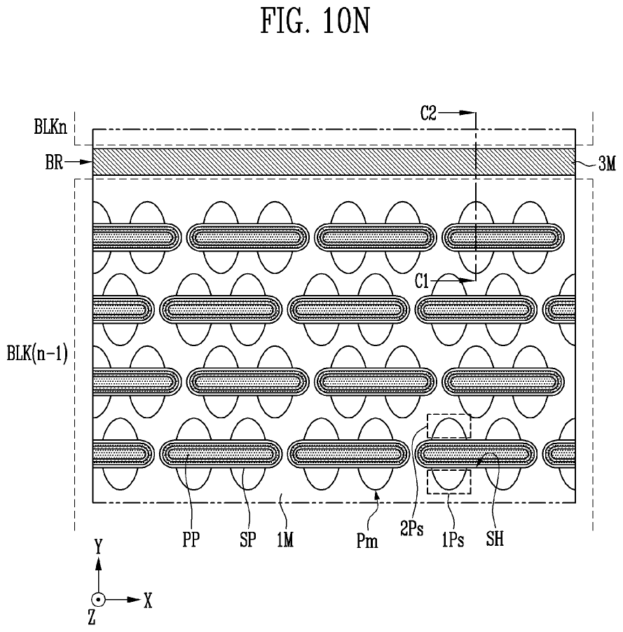

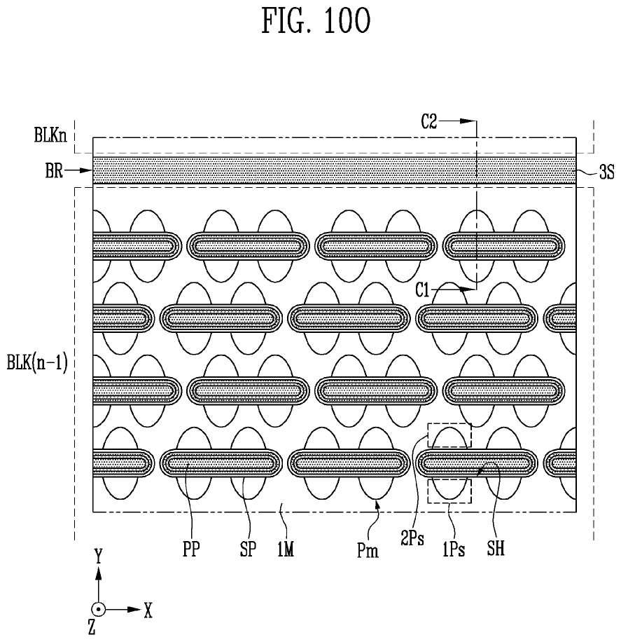

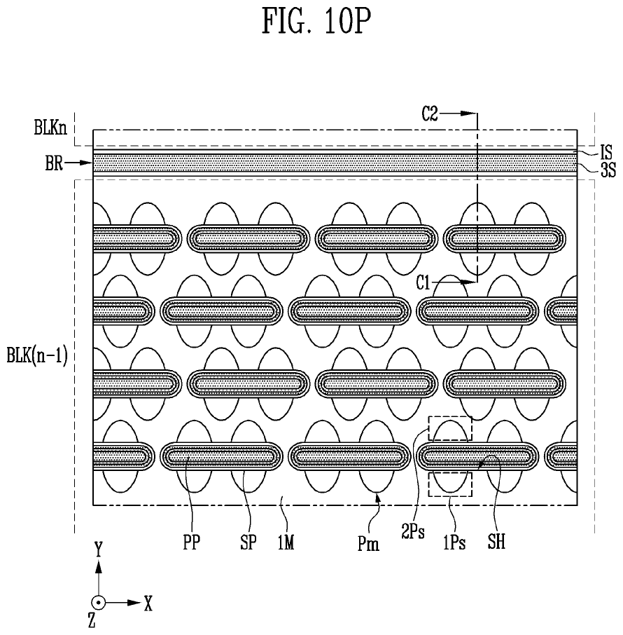

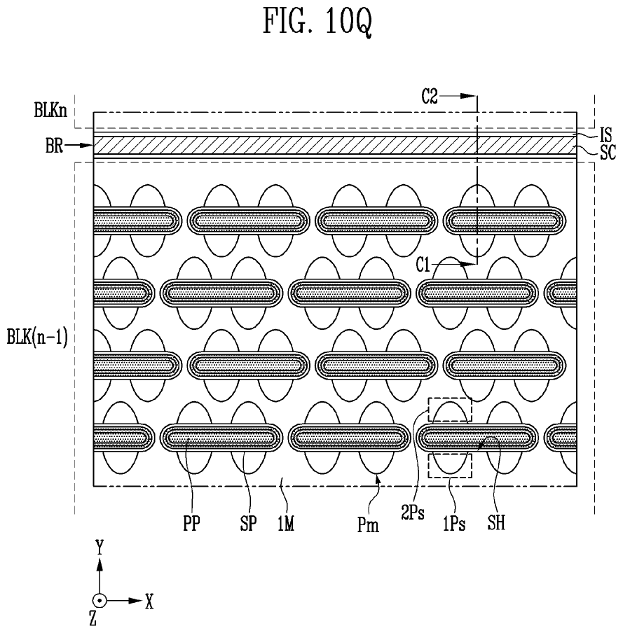

FIGS. 10A to 10Q are layout views illustrating a method of manufacturing a memory device according to an embodiment of the present disclosure. FIGS. 11A to 11Q are cross-sectional diagrams illustrating a method of manufacturing a memory device according to an embodiment of the present disclosure.

FIGS. 11A to 11Q are layout views illustrating a cross-section taken along line C1-C2 of FIGS. 10A to 10Q, respectively.

Referring to FIGS. 10A and 11A, a first source layer 1S, a sacrificial layer SF and a second source layer 2S may be stacked on a lower structure (not shown). The lower structure (not shown) may include a substrate or peripheral circuits. The first source layer 1S may serve as a source line and include a conductive material. The second source layer 2S may have the same material as the first source layer 1S. For example, the first source layer 1S and the second source layer 2S may include a conductive material such as polysilicon, tungsten, or nickel. The sacrificial layer SF may include a material having an etch selectivity with respect to the first source layer 1S. An etch stop layer ST may be formed in a portion of the sacrificial layer SF. During an etch process for forming a slit hole SLH in a slit region, the etch stop layer ST may be provided to prevent or mitigate over-etching. The etch stop layer ST may include a conductive material such as tungsten. During subsequent processes, to protect the first and second source layers 1S and 2S, a buffer layer may be further formed between the first source layer 1S and the sacrificial layer SF and between the second source layer 2S and the sacrificial layer SF. For example, the buffer layer may include an oxide layer.

Referring to FIGS. 10B and 11B, first and second material layers 1M and 2M may be alternately stacked over the second source layer 2S. For example, when the first material layer 1M is formed over the second source layer 2S, the second material layer 2M may be formed over the first material layer 1M, and the first material layer 1M may be formed over the second material layer 2M. The first material layer 1M may include an insulating material. For example, the first material layer 1M may include an oxide layer or a silicon oxide layer. The second material layer 2M may include a material which is removable during a subsequent process. Therefore, the second material layer 2M may include a material having a different etch selectivity from the first material layer 1M. For example, the second material layer 2M may include a nitride layer. The first material layer 1M may be formed on both top and bottom of the structure in which the first and second material layers 1M and 2M are stacked.

Referring to FIGS. 10C and 11C, a vertical hole VH through which the first source layer 1S is exposed may be formed in a cell region of a memory block. For example, an etch process may be performed to remove portions of the first and second material layers 1M and 2M and portions of the second source layer 2S, the sacrificial layer SF, and the first source layer 1S. As the etch process, a dry etch process may be performed so that the vertical hole VH may be formed in the vertical direction to the substrate. The vertical hole VH may be formed in a region for forming a main plug. A major axis of the vertical hole VH may represent a Y direction and a minor axis thereof may represent an X direction. When the etch process for forming the vertical hole VH is terminated, the first source layer 1S may be exposed through a lower surface of the vertical hole VH, and the first and second material layers 1M and 2M, the second source layer 2S and the sacrificial layer SF may be exposed through a side surface of the vertical hole VH.

Referring to FIGS. 10D and 11D, the main plug Pm may be formed in the vertical hole VH. The main plug Pm may include the blocking layer BX, the charge trap layer CT, the tunnel isolation layer TO, the channel layer CH, the core pillar CP, and the capping layer CAP. For example, the blocking layer BX may be formed along an inner surface of the vertical hole VH having a cylindrical shape. The cylindrical shape of the blocking layer BX may be defined to fill a portion of the inside of the vertical hole VH. The charge trap layer CT may have a cylindrical shape along an inner surface of the blocking layer BX. The tunnel isolation layer TO may have a cylindrical shape along an inner surface of the charge trap layer CT. The channel layer CH may have a cylindrical shape along an inner surface of the tunnel isolation layer TO. The core pillar CP may fill the inside surrounded by the channel layer CH. After the core pillar CP is formed, an etch process may be performed to remove a portion of the upper region of the core pillar CP. The capping layer CAP may be formed in a region from which the core pillar CP is removed.

Referring to FIGS. 10E and 11E, the separation hole SH for separating the main plug Pm in the Y-axis direction may be formed. The separation hole SH may be formed by an etch process for removing a portion of the main plug Pm. The etch process may be performed until the first source layer 1S in the cell region is exposed so that the channel layer CH included in the main plug Pm may be separated. When the etch process for forming the separation hole SH is terminated, the first source layer 1S may be exposed through the bottom surface of the separation hole SH, and the blocking layer BX, the charge trap layer CT, the tunnel isolation layer TO, the channel layer CH, the core pillar CP, and the capping layer CAP may be exposed through the side surface of the separation hole SH. As the etch process, a dry etch process may be performed so that the separation hole SH may be formed in a vertical direction to the substrate. The main plug Pm may be separated into the first sub-plug 1Ps and the second sub-plug 2Ps by the separation hole SH.

FIGS. 10F to 10H and 11F to 11H are layout views and cross-sectional views illustrating a method of manufacturing the separation layer SM according to an embodiment of the present disclosure.

Referring to FIGS. 10F and 11F, the first separation layer 1SM may be formed in the separation hole SH. The first separation layer 1SM may have a curved side wall. The first separation layer 1SM may have a cylindrical shape which does not fill the separation hole SH along the inner wall of the separation hole SH. The first separation layer 1SM may include an insulating material, for example, an oxide layer or a silicon oxide layer. The first separation layer 1SM may, in an embodiment, protect layers which are exposed through the side surface of the separation hole SH, and may electrically block the second separation layer 2SM and the first to fourth sub-plugs 1Ps to 4Ps from each other. In addition, the first separation layer 1SM may, in an embodiment, block a source line conductive material from being introduced into memory cells during a source line forming process to be performed in subsequent processes.

Referring to FIGS. 10G and 11G, the second separation layer 2SM may be formed along the inner wall of the separation hole SH in which the first separation layer 1SM is formed. The second separation layer 2SM may include a low-k material, for example, a SiCN layer. To control capacitance of a memory cell, the carbon (C) content of the second separation layer 2SM may be adjusted. For example, the capacitance of the second separation layer 2SM may be in proportion to the concentration of carbon (C) included in the second separation layer 2SM. In an embodiment, the second separation layer 2SM may be provided to reduce interference between memory cells which oppose each other with the separation layer SM interposed therebetween. In an embodiment, the second separation layer 2SM may block a source line conductive material together with the first separation layer 1SM from being introduced into memory cells during the source line forming process to be performed in subsequent processes.

Referring to FIGS. 10H and 11H, the third separation layer 3SM may be formed in the separation hole SH in which the second separation layer 2SM is formed. The third separation layer 3SM may have a curved side wall. The third separation layer 3SM may have cylindrical shape which does not fill the separation hole SH along the inner wall of the second separation layer 2SM. The third separation layer 3SM may include an insulating material. For example, the third separation layer 3SM may include a silicon oxide layer or an oxide layer. In an embodiment, the third separation layer 3SM may block a source line conductive material together with the first and second separation layers 1SM and 2SM from being introduced into memory cells during the source line forming process to be performed in subsequent processes.

Referring to FIGS. 10I and 11I, the blocking pattern PP may be formed over the entire structure. The blocking pattern PP may include a material with a high step coverage to cover top portions of the slit hole SLH and the third separation layer 3SM before the insides of the slit hole SLH and the separation hole SH filled with the third separation layer 3SM are filled. The blocking pattern PP may have an oxide layer with a higher step coverage than the first material layer 1M. Since a material with a high step coverage has a faster deposition speed than a general material, top open portions of the slit hole SLH and the separation hole SH filled with the third separation layer 3SM may be closed before deep holes, such as the slit hole SLH and the separation hole SH, are filled.

Referring to FIGS. 103 and 113, an etch process may be performed such that the blocking pattern PP may remain in the top portion of the separation hole SH filled with the third separation layer 3SM while the blocking pattern PP formed in the other areas may be removed. For example, a planarizing process may be performed until the first material layer 1M or the capping layer CAP is exposed. When the planarizing process is performed, the blocking pattern PP may be removed from the top portions of the slit hole SLH, the first material layer 1M, and the first and second sub-plugs 1Ps and 2Ps, whereas the blocking pattern PP may remain in the separation hole SH filled with the third separation layer 3SM. As a result, the etch stop layer ST and the first and second material layers 1M and 2M may be exposed through the slit hole SLH.

Referring to FIGS. 10K and 11K, an etch process may be performed to remove the etch stop layer ST exposed through the slit hole SLH. Since the sacrificial layer SF is exposed through the slit hole SLH after the etch stop layer ST is removed, the etch process may be performed to remove the sacrificial layer SF. When the sacrificial layer SF is removed, the blocking layer BX between the first and second source layers 1S and 2S may be exposed. When the blocking layer BX is exposed, a wet etch process may be performed to remove the blocking layer BX, the charge trap layer CT, and the tunnel isolation layer TO which are exposed between the slit SLT and the first and second source layers 1S and 2S. The etch process for removing the charge trap layer CT and the tunnel isolation layer TO may be performed until the channel layer CH is removed. Since the wet etch process is performed, the first separation layer 1SM exposed between the first and second source layers 1S and 2S may be removed together with the blocking layer BX. However, the first separation layer 1SM in the sub-separation region SMs might not be removed since the first separation layer 1SM is protected by the first to fourth sub-plugs 1Ps to 4Ps.

Referring to FIGS. 10L and 11L, the third source layer 3S may be formed in the region from which the sacrificial layer SF, the charge trap layer CT, the tunnel isolation layer TO, and the first separation layer 1SM exposed through the slit hole SLH are removed. The third source layer 3S may contact the channel layer CH at the bottom surface of the main plug Pm. The third source layer 3S may include the same material as the first or second source layer 1S or 2S. For example, the third source layer 3S may include a conductive material such as polysilicon, tungsten, or nickel. Therefore, the source line SL which consist of the first to third source layers 1S to 3S may be formed. The first to third separation layers 1SM to 3SM may be used to block the source line conductive material from being introduced into the memory cells.

Referring to FIGS. 10M and 11M, an etch process may be performed to remove the second material layer 2M through the slit hole SLH. As the etch process, a wet etch process using an etchant for selective removal may be performed such that the first material layer 1M may remain while the second material layer 2M is removed.

Referring to FIGS. 10N and 11N, the third material layer 3M may be formed in the region from which the second material layer 2M is removed. Since the third material layer 3M serves as the gate line GL, the third material layer 3M may include a conductive material. For example, the third material layer 3M may include tungsten (W), cobalt (Co), nickel (Ni), molybdenum (Mo), silicon (Si), and polysilicon (Poly-Si). When the third material layer 3M is formed between the first material layers 1M, the stacked structure including the first and third material layers 1M and 3M may be formed. When the third material layer 3M is formed between the first material layers 1M, the third material layer 3M may also be formed on the surface of the slit hole SLH.

Referring to FIGS. 10O and 11O, an etch process may be performed to remove the third material layer 3M formed on the surface of the slit hole SLH. The etch process may be performed to remove the third material layer 3M from the surface of the slit hole SLH. However, a portion of the third material layer 3M which is adjacent to the slit hole SLH between the first material layers 1M may also be removed.

Referring to FIGS. 10P and 11P, the slit isolation layer IS may be formed on the surface of the slit hole SHL. The slit isolation layer IS may include an oxide layer or a silicon oxide layer. The slit isolation layer IS may be formed to cover the entire third material layer 3M exposed through the side surface of the slit hole SLH. The slit isolation layer IS may be formed under the slit hole SLH. After the slit isolation layer IS is formed, an etch process may be performed to expose the third source layer 3S through the bottom surface of the slit hole SLH. As the etch process, a dry etch process may be performed such that the slit isolation layer IS formed on the side surface of the slit hole SLH may be maintained whereas the slit isolation layer IS formed at the bottom surface of the slit hole SLH may be selectively removed.

Referring to FIGS. 10Q and 11Q, a deposition process may be performed to form the source contact SC in the slit hole SLH. The source contact SC may include a conductive material. For example, the source contact SC may include doped polysilicon or tungsten. The slit isolation layer IS may be formed between the third material layer 3M for the gate lines GL and the source contact SC. Therefore, the gate lines GL included in the (n−1)th and nth memory blocks BLK(n−1) and BLKn may be separated from each other.

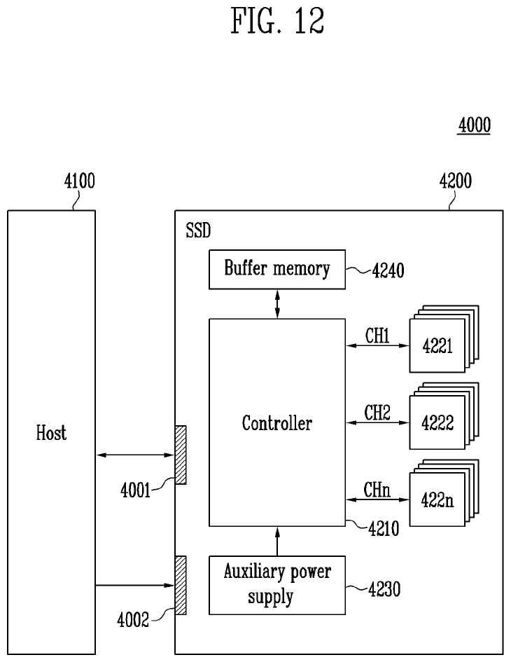

FIG. 12 is a block diagram illustrating a solid state drive (SSD) system 4000 to which a memory device according to an embodiment of the present disclosure is applied.

Referring to FIG. 12, the SSD system 4000 may include a host 4100 and an SSD 4200. The SSD 4200 may exchange signals with the host 4100 through a signal connector 4001 and may receive power through a power connector 4002. The SSD 4200 may include a controller 4210, a plurality of flash memories 4221 to 422n, an auxiliary power supply 4230, and a buffer memory 4240.

The controller 4210 may control the plurality of flash memories 4221 to 422n in response to the signals received from the host 4100. In an embodiment, the signals may be based on the interfaces of the host 4100 and the SSD 4200. For example, the signals may be defined by at least one of various interfaces such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe) interfaces.

The auxiliary power supply 4230 may be coupled to the host 4100 through the power connector 4002. The auxiliary power supply 4230 may be supplied and charged with the power from the host 4100. The auxiliary power supply 4230 may supply the power of the SSD 4200 when the power is not smoothly supplied from the host 4100. In an embodiment, the auxiliary power supply 4230 may be positioned inside or outside the SSD 4200. For example, the auxiliary power supply 4230 may be disposed in a main board and supply auxiliary power to the SSD 4200.

The buffer memory 4240 may serve as a buffer memory of the SSD 4200. For example, the buffer memory 4240 may temporarily store data received from the host 4100 or data received from the plurality of flash memories 4221 to 422n, or may store metadata (e.g., mapping tables) of the flash memories 4221 to 422n. The buffer memory 4240 may include volatile memories such as DRAM, SDRAM, DDR SDRAM, LPDDR SDRAM, and GRAM, or nonvolatile memories such as FRAM, ReRAM, STT-MRAM, and PRAM.

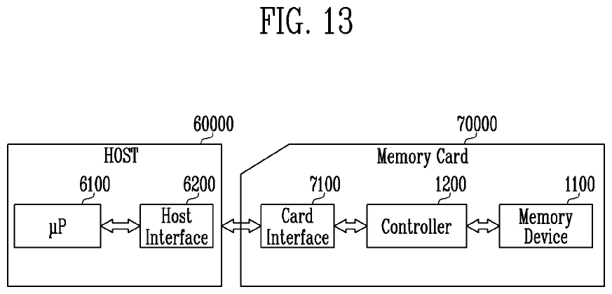

FIG. 13 is a diagram illustrating a memory system 70000 to which a memory device according to an embodiment of the present disclosure is applied.

Referring to FIG. 13, the memory system 70000 may include a memory card or a smart card. The memory system 70000 may include a memory device 1100, a controller 1200, and a card interface 7100.

The memory device 1100 may be configured in the same manner as the memory device 100 as shown above in FIG. 1.

The controller 1200 may control data exchange between the memory device 1100 and the card interface 7100. According to an embodiment, the card interface 7100 may be, but is not limited thereto, a secure digital (SD) card interface or a multi-media card (MMC) interface.

The card interface 7100 may interface data exchange between a host 60000 and the controller 1200 according to a protocol of the host 60000. According to an embodiment, the card interface 7100 may support a Universal Serial Bus (USB) protocol and an InterChip (IC)-USB protocol. The card interface 7100 may refer to hardware capable of supporting a protocol which is used by the host 60000, software installed in the hardware, or a signal transmission method.

When the memory system 70000 is connected to a host interface 6200 of the host 60000 such as a PC, a tablet PC, a digital camera, a digital audio player, a cellular phone, console video game hardware, or a digital set-top box, the host interface 6200 may perform data communication with the memory device 1100 through the card interface 7100 and the controller 1200 in response to control of a microprocessor 6100.

According to an embodiment, the reliability of the memory device may be improved.

It will be apparent to those skilled in the art that various modifications can be made to the above-described examples of embodiments without departing from the spirit or scope of the disclosure. Thus, it is intended that the present disclosure cover all such modifications provided they come within the scope of the appended claims and their equivalents.

What is claimed is:

1. A memory device, comprising:
a stacked structure including gate lines, wherein the gate lines are stacked in a vertical direction, and wherein the gate lines are separated from each other;
a main plug included in the stacked structure, the main plug extended in the vertical direction of the stacked structure;
a plug separation pattern separating the main plug into first and second sub-plugs;
a gap included in the plug separation pattern; and
a separation layer surrounding the gap.

2. The memory device of claim 1, wherein the separation layer includes a first separation layer, a second separation layer, and a third separation layer.

3. The memory device of claim 2, wherein the gap is surrounded by the third separation layer, the third separation layer has a curved side wall,
the second separation layer surrounds the curved side wall of the third separation layer, and
the first separation layer surrounds the curved side wall of the second separation layer.

4. The memory device of claim 2, wherein each of the first separation layer and the third separation layer includes an insulating material.

5. The memory device of claim 2, wherein the second separation layer includes a low-k material.

6. The memory device of claim 5, wherein the low-k material includes SiCN.

7. The memory device of claim 6, wherein capacitance of the second separation layer is controlled by a concentration of carbon (C) included in the SiCN.

8. The memory device of claim 1, wherein the main plug includes a core pillar, a channel layer, a tunnel isolation layer, a charge trap layer, and a blocking layer extending in the stacked structure.

9. The memory device of claim 1, wherein the first and second sub-plugs are substantially symmetrical to each other with respect to the plug separation pattern.

10. The memory device of claim 1, wherein the plug separation pattern extends in the main plug and the stacked structure.

11. The memory device of claim 9, wherein the gap and the first to third separation layers are formed in the plug separation pattern to extend in the main plug and the stacked structure.

12. The memory device of claim 1, wherein the plug separation pattern includes a blocking pattern surrounded by the separation layer over the gap.

13. The memory device of claim 2, wherein the separation layer includes a sub-separation region contacting the first and second sub-plugs.

14. The memory device of claim 13, except for the sub-separation region, and the second separation layer directly contacts the source line.

15. The memory device of claim 14, wherein the first separation layer overlaps with the first and second sub-plugs.

16. The memory device of claim 1, wherein the gap constitutes an air gap.

17. The memory device of claim 1, wherein the gap includes a gas.

18. A method of manufacturing a memory device, the method comprising:
forming a stacked structure in which first and second material layers are alternately stacked in a vertical direction over a lower structure,
forming main plugs included in the stacked structure, the main plugs spaced apart from each other and arranged in the vertical direction of the stacked structure;
forming slit holes passing through the stacked structure and separation holes for separating the main plugs;
forming a first separation layer on an inner side surface of each of the separation holes;
forming a second separation layer on an inner side surface of the first separation layer;
forming a third separation layer on an inner side surface of the second separation layer; and
forming a gap in the third separation layer.

19. The method of claim 18, further comprising:
removing a sacrificial layer exposed through the slit holes;
filling removed portions of the sacrificial layer with a third material layer;
removing the second material layers exposed through the slit holes;
forming conductive layers on portions from which the second material layers are removed;
forming an insulating layer on sides of the slit holes; and
forming a source contact in the slit holes in which the insulating layer is formed.

20. The method of claim 18, wherein the forming of the gap comprises:
forming a blocking pattern over an entire top portion of the stacked structure; and
removing the blocking pattern except for the blocking pattern formed over the third separation layer.

21. The method of claim 18, wherein the first material layers include an oxide layer, and
the second material layers include an oxide layer.

22. The method of claim 18, wherein the forming of the main plugs comprises:
forming vertical holes passing through the first and second material layers; and
forming a blocking layer, a charge trap layer, a tunnel isolation layer, a channel layer, and a core pillar along an inner wall of each of the vertical holes.

23. The method of claim 18, wherein each of the first and third separation layers include an insulating material.

24. The method of claim 18, wherein the second separation layer includes a low-k material.

25. The method of claim 24, wherein the low-k material includes SiCN.

26. The method of claim 25, wherein capacitance of the second separation layer is controlled by a concentration of carbon (C) included in SiCN.
